(19) United States
(12) Patent Application Publication
(10) Pub. No.: US 2017/0170672 A1
(43) Pub. Date: Jun. 15, 2017

(54) SHORTING BATTERY TO GROUND RESPONSIVE TO BATTERY IMPEDANCE REACHING THRESHOLD

(71) Applicant: LENOVO (SINGAPORE) PTE. LTD., New Tech Park (SG)

(72) Inventors: Bouziane Yebka, Apex, NC (US); Joseph Anthony Holung, Wake Forest, NC (US); Tin-Lup Wong, Chapel Hill, NC (US); Philip John Jakes, Durham, NC (US)

(21) Appl. No.: 14/963,532

(22) Filed: Dec. 9, 2015

(51) Int. Cl. H02J 7/00; H01M 10/48; G01R 31/36

(52) U.S. Cl. CPC H02J 7/0029; G01R 31/3662; H01M 10/486; G01R 31/3606; H02J 2007/0037; H02J 2007/0095

(57) ABSTRACT

In one aspect, a device includes a processor, at least one system component accessible to the processor. a battery which powers the processor and the at least one system component, an impedance sensor that is accessible to the processor and that senses impedance of the battery, and storage accessible to the processor. The storage bears instructions executable by the processor to receive input from the impedance sensor regarding an impedance of the battery and, based at least in pan on the input, determine whether to perform at least one action to at least attempt to bring impedance of the battery below an impedance threshold.

### FIELD

The present application relates generally to batteries.

### BACKGROUND

As recognized herein, swelling of a battery can occur based tin a number of factors, such as temperatures to which it is exposed, the number of times it has been charged, the amount of charge it receives, etc. Battery swelling can lead to a number of undesirable consequences, particularly when the battery swells to excess, such as the battery exploding or ejecting components, which in turn may physically harm a person near the battery. As also recognized herein, there are currently no adequate ways to address this.

### SUMMARY

Accordingly, in one aspect a device includes a processor, at least one system component accessible to the processor, a bartery which powers the processor and the at least one system component, an impedance sensor that is accessible to the processor and that senses impedance of the battery, and storage accessible to the processor. The storage bears instructions executable by the processor to receive input from the impedance sensor regarding an impedance of the battery and, based at least in part on the input, determine whether to perform at least one action to at least attempt to bring impedance of the battery below an impedance threshold.

In another aspect, a method includes receiving input from a battery impedance sensor regarding an impedance of a battery and determining whether the impedance of the battery is above an impedance threshold based at least in part on the input.

In still another aspect, a battery pack includes a battery, an impedance sensor which senses an impedance of the battery, and a processor powered by the battery and communicatively coupled to the impedance sensor. The processor receives input from the impedance sensor and determines, based at least in part on the input, whether the impedance of the battery is above a threshold.

The details of present principles, both as to their structure and operation, can best be understood in reference to the accompanying drawings, in which like reference numerals refer to like parts, and in which:

### BRIEF DESCRIPTION OF THE DRAWINGS

FIG. 1 is a block diagram of an example system in accordance with present principles;

FIG. 2 is a block diagram of a network of devices in accordance with present principles;

FIG. 3 is a flow chart showing an example algorithm in accordance with present principles:

FIG. 4 is an example user interface (UI) in accordance with present principles;

FIG. 5 is an example prompt in accordance with present principles;

FIGS. 6-8 are block diagrams of example battery circuitry in accordance with present principles;

FIGS. 9A and 9B are block diagrams of example electrical components in accordance with present principles:

FIGS. 10-13 show graphs in accordance with present principles; and

FIGS. 14 and 15 are illustrations of present principles.

### DETAILED DESCRIPTION

With respect to any computer systems discussed herein, a system may include server and client components, connected over a network such that data may be exchanged between the client and server components. The client components may include one or more computing devices including televisions (e.g., smart TVs, Internet-enabled TVs), computers such as desktops, laptops and tablet computers, so-called convertible devices (e.g., having a tablet configuration and laptop configuration), and other mobile devices including smart phones. These client devices may employ, as non-limiting examples, operating systems from Apple, Google, or Microsoft. A Unix or similar such as Linux operating system may be used. These operating systems can execute one or more browsers such as a browser made by Microsoft or Google or Mozilla or other browser program that can access web applications hosted by the Internet servers over a network such as the Internet, a local intranet, or a virtual private network.

As used herein, instructions refer to computer-implemented steps for processing information in the system. Instructions can be implemented in software, firmware or hardware; hence, illustrative components, blocks, modules, circuits, and steps are set forth in terms of their functionality.

A processor may be any conventional general purpose single- or multi-chip processor that can execute logic by means of various lines such as address lines, data lines, and control lines and registers and shift registers. Moreover, any logical blocks, modules, and circuits described herein can be implemented or performed, in addition to a general purpose processor, in or by a digital signal processor (DSP), a field programmable gate array (FPGA) or other programmable logic device such as an application specific integrated circuit (ASIC), discrete gale or transistor logic, discrete hardware components, or any combination thereof designed to perform the functions described herein. A processor can be implemented by a controller or state machine or a combination of computing devices.

Any software and/or applications described by way of flow charts and/or user interfaces herein can include various sub-routines, procedures, etc. It is to be understood that logic divulged as being executed by, e.g., a module can be redistributed lo Other software modules and/or combined together in a single module and/or made available in a shareable library.

Logic when implemented in software, can be written in an appropriate language such as but not limited to C# or C++, and can be stored on or transmitted through a computer-readable storage medium (e.g., that may not be a transitory signal) such as a random access memory (RAM), read-only memory (ROM), electrically erasable programmable read-only memory (EEPROM), compact disk read-only memory (CD-ROM) or other optical disk storage such as digital versatile disc (DVD), magnetic disk storage or other magnetic storage devices including removable thumb drives, etc. A connection may establish a computer-readable medium. Such connections can include, as examples, hard-wired cables including fiber optics and coaxial wires and twisted pair wires. Such connections may include wireless communication connections including infrared and radio.

In an example, a processor can access information over its input lines from data storage, such as the computer readable storage medium, and or the processor can access information wirelessly from an Internet server by activating a wireless transceiver to send and receive data. Data typically is converted from analog signals to digital by circuitry between the antenna and the registers of the processor when being received and from digital to analog when being transmitted. The processor then processes the data through its shift registers to output calculated data on output lines, for presentation of the calculated data on the device.

Components included in one embodiment can be used in other embodiments in any appropriate combination. For example, any of the various components described herein and/or depicted in the Figures may be combined, interchanged or excluded from other embodiments.

“A system having at least one of A, B. and C” (likewise “a system having at least one of A, B, or C” and “a system having at least one of A, B, C”) includes systems that have A alone, B alone, C alone, A and B together, A and C together, B and C together, and/or A, B, and C together, etc.

“A system having one or more of A, B, and C” (likewise “a system having one or more of A, B, or C” and “a system having one or more of A, B, C”) includes systems that have A alone, B alone, C alone, A and B together, A and C together, B and C together, and/or A, B, and C together, etc.

The term “circuit” or “circuitry” may be used in the summary, description, and/or claims. As is well known in the art, the term “circuitry” includes all levels of available integration, e.g., from discrete logic circuits to the highest level of circuit integration such as VLSI, and includes programmable logic components programmed to perform the functions of an embodiment as well as general-purpose or special-purpose processors programmed with instructions to perform those functions.

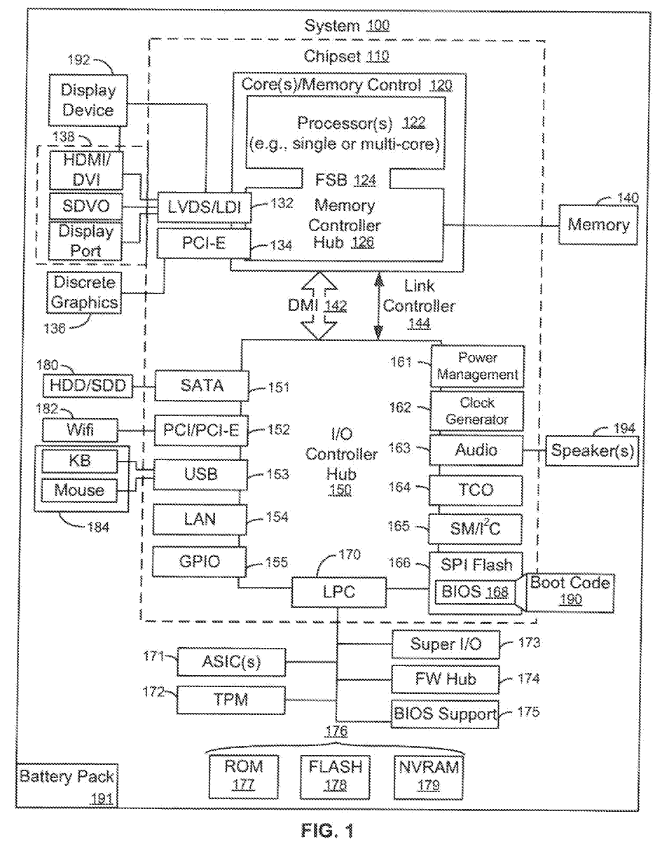

Now specifically in reference to FIG. 1 , an example block diagram of an information handling system and/or computer system 100 is shown. Note that in some embodiments the system 100 may be a desktop computer system, such as one of the ThinkCentre® or ThinkPad® series of personal computers sold by Lenovo (US) Inc. of Morrisville, N.C., or a workstation computer, such as the ThinkStation®, which are sold by Lenovo (US) Inc. of Morrisville, N.C.; however, as apparent from the description herein, a client device, a server or other machine in accordance with present principles may include other features or only some of the features of the system 100. Also, the system 100 may be, e.g., a game console such as XBOX® or Playstation®, and/or the system 100 may include a wireless telephone, notebook computer, and/or other portable computerized device.

As shown in FIG. 1, the system 100 may include a so-called chipset 110. A chipset refers to a group of integrated circuits, or chips, that are designed to work together. Chipsets are usually marketed as a single product (e.g.. consider chipsets marketed under the brands INTEL®, AMD®, etc.).

In the example of FIG. 1, the chipset 110 has a particular architecture, which may vary to some extent depending on brand or manufacturer. The architecture of the chipset 110 includes a core and memory control group 120 and an I/O controller hub 150 that exchange information (e.g., data, signals, commands, etc.) via, for example, a direct management interface or direct media interlace (DMI) 142 or a link controller 144. In the example of FIG. 1, the DMI 142 is a chip-to-chip interface (sometimes referred to as being a link between a “northbridge” and a “southbridge”).

The core and memory control group 120 include one or more processors 122 (e.g., single core or multi-core, etc.) and a memory controller hub 126 that exchange information via a front side bus (FSB) 124. As described herein, various components of the core and memory control group 120 may be integrated onto a single processor die, for example, to make a chip that supplants the conventional “northbridge” style architecture.

The memory controller hub 126 interlaces with memory 140. For example, the memory controller hub 126 may provide support for DDR SDRAM memory (e.g., DDR, DDR2, DDR3, etc.). In general, the memory 140 is a type of random-access memory (RAM). It is often referred to as “system memory.”

The memory controller hub 126 can further include a low-voltage differential signaling interface (LVDS) 132. The LVDS 132 may be a so-called LVDS Display Interface (LDI) for support of a display device 192 (e.g., a CRT, a fiat panel, a projector, a touch-enabled display, etc.). A block 138 includes some examples of technologies that may be supported via the LVDS interface 132 (e.g., serial digital video. HDMI/DVI, display port). The memory controller hub 126 also includes one or more PCI-express interfaces (PCI-E) 134. for example, for support of discrete graphics 136. Discrete graphics using a PCI-E interface has become an alternative approach to an accelerated graphics port (AGP). For example, me memory controller huh 126 may include a 16-lane (×16) PCI-E port for an external PCI-E-based graphics card (including, e.g., one of more GPUs). An example system may include AGP or PCI-E for support of graphics.

In examples in which it is used, the I/O huh controller) 150 can include a variety of interfaces. The example of FIG. 1 includes a SATA interface 151, one or more PCI-E interfaces 152 (optionally one or more legacy PCI interfaces), one or more USB interfaces 153, a LAN interface 154 (more generally a network interface for communication over at least one network such as the Internet, a WAN, a LAN, etc. under direction of the processors) 122), a general purpose I/O interface (GPIO) 155, a low-pin count (LPC) interface 170, a power management interface 161, a clock generator interface 162, an audio interface 163 (e.g.. for speakers 194 to output audio), a total cost of operation (TCO) interface 164, a system management bus interface (e.g., a multi-master serial computer bus interface) 165, and a serial peripheral flash memory/controller interface (SPI Flash) 166, which, in the example of FIG. 1, includes BIOS 168 and boot code 190. With respect to network connections, the I/O hub controller 150 may include integrated gigabit Ethernet controller lines multiplexed with a PCI-E interface port. Other network features may operate independent of a PCI-E interface.

The interlaces of the I/O hub controller 150 may provide for communication with various devices, networks, etc. For example, where used, the SATA interface 151 provides for reading, writing or reading and writing information on one or more drives 180 such as HDDs, SDDs or a combination thereof, but in any case the drives 180 are understood to be, e.g., tangible computer readable storage mediums that may not be transitory signals. The I/O hub controller 150 may also include an advanced host controller interface (AHCI) to support one or more drives 180. The PCI-E interface 152 allows for wireless connections 182 to devices, networks, etc. The USB interface 153 provides for input devices 184 such as keyboards (KB), mice and various other devices (e.g., cameras, phones, storage, media players, etc.).

In the example of FIG. 1, the LPC interface 170 provides for use of one or more ASICs 171, a trusted platform module (TPM) 172, a super I/O 173, a firmware hub 174, BIOS support 175 as well as various types of memory 176 such as ROM 177, Flash 178, and non-volatile RAM (NVRAM) 179. With respect to the TPM 172, this module may be in the form of a chip that can be used to authenticate software and hardware devices. For example, a TPM may be capable of performing platform authentication and may be used to verify that a system seeking access is the expected system.

The system 100, upon power on. may be configured to execute boot code 190 for the BIOS 168, as stored within the SPI Flash 166, and thereafter processes data under the control of one or more operating systems and application software (e.g., stored in system memory 140). An operating system may be stored in any of a variety of locations and accessed, for example, according to instructions of the BIOS 168.

Furthermore, the system 100 may also include at least one battery pack 191 comprising at least one battery and/or battery cell. The battery pack 191 may be in jelly roll format or pouch cell format in which the strip(s) of active material are folded, and in cither case may be a Lithium ion battery. The battery pack 191 may be electrically coupled to and power the system 100, and can also be electrically coupled to at least one charge receiver on the system 100 for receiving a charge. The charge receiver can include at least one circuit configured for receiving power (e.g., from a wall outlet) and doing at least one of: providing current to the system 100 to power it, and providing current to the battery pack 191 to charge at least one battery in the pack 191. The battery pack 191 may also include a battery management unit/system (BMU) that itself may include elements such as a processor, random access memory (RAM), and non-volatile storage bearing instructions executable by the BMU's processor. The battery pack 191 may further include one or more sensors for sensing and measuring things related to the battery pack 191 and/or battery within, such as voltage, age, impedance, state of charge, temperature, current, etc. The sensors may provide input/measurements to the BMU's processor and/or the processors 122. Still further, it is to be understood that the battery pack 191 may comprise one or more elements for shorting the battery within the pack 191 to ground, for rendering the battery (e.g., permanently) inoperable, for initiating a (e.g., permanent) failure of the battery, etc., as will be described further below.

Additionally, though now shown for clarity, in some embodiments the system 100 may include a gyroscope that senses and/or measures the orientation of the system 100 and provides input related thereto to the processor 122, an accelerometer that senses acceleration and/or movement of the system 100 and provides input related thereto to the processor 122. an audio receiver/microphone that provides input to the processor 122 based on audio that is detected, such as via a user providing audible input to the microphone, and a camera that gathers one or more images and provides input related thereto to the processor 122. The camera may be a thermal imaging camera, a digital camera such as a webcam, a three-dimensional (3D) camera, and/or a camera otherwise integrated into the system 100 and controllable by the processor 122 to gather pictures images and or video. Still further, and also not shown for clarity, the system 100 may include a GPS transceiver that is configured to receive geographic position information from at least one satellite and provide the information to the processor 122. However, it is to be understood that another suitable position receiver other than a GPS receiver may be used in accordance with present principles to determine the location of the system 100.

It is to be understood that an example client device or other machine/computer may include fewer or more features than shown on the system 100 of FIG. 1. In any case, it is to be understood at least based on the foregoing that the system 100 is configured to undertake present principles.

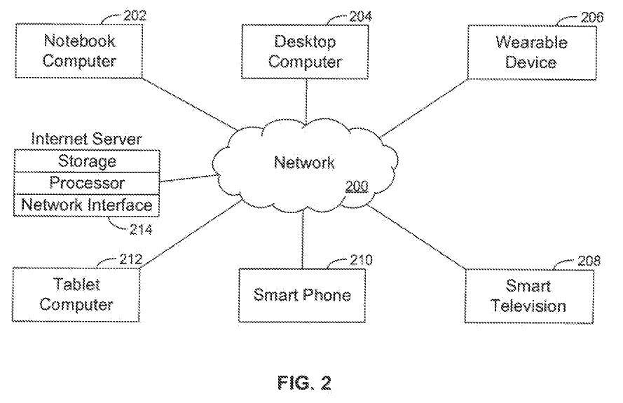

Turning now to FIG. 2, example devices are shown communicating over a network 200 such as the Internet in accordance with present principles. It is to be understood that each of the devices described in reference to FIG. 2 may include at least some of the features, components, and/or elements of the system 100 described above.

FIG. 2 shows a notebook computer and/or convertible computer 202, a desktop computer 204, a wearable device 206 such as a smart watch, a smart television (TV) 208, a smart phone 210, a tablet computer 212, and a server 214 such as an Internet server that may provide cloud storage accessible to the devices 202-212. It is to be understood that the devices 202-214 are configured to communicate with each other over the network 200 to undertake present principles.

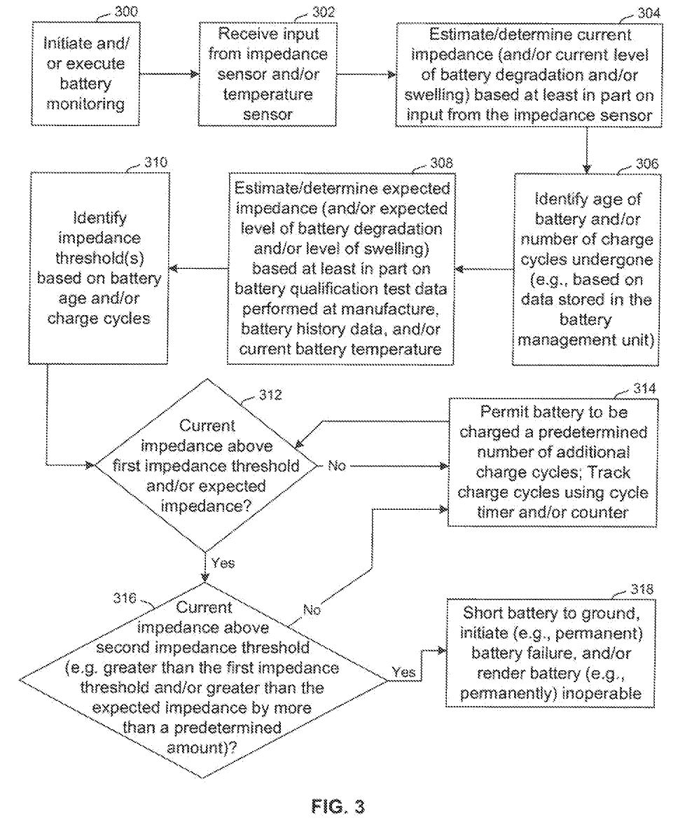

Referring to FIG. 3, it shows example logic in accordance with present principles that may be executed by a processor in a device such as the system 100 and/or a processor in a battery pack such as the pack 191 to determine whether impedance of a battery has exceeded a threshold and/or whether the battery should be shorted to ground. Beginning at block 300. the logic initiates and-or executes monitoring of the battery, such as by launching one or more processes and or applications for doing so. The logic then moves to block 302 where the logic receives input from an impedance sensor that senses impedance of the battery, and receives input from a temperature sensor that senses temperature of the battery.

From block 302 the logic next moves to block 304, where the logic, based on the input(s) received at block 302, estimates and/or determines an actual, current impedance of the battery in real time as the battery continues to operate. Furthermore, in some embodiments at block 304 and at least in part based on the input received al block 302, the logic may, in real time as the battery continues to operate, also estimate and/r determine an actual current level of battery degradation and or an actual current amount of battery swelling, e.g., based on current degradation/swelling being directly correlatable to current battery impedance (and/or, in some embodiments, buttery temperature). Thus, for instance, degradation/swelling may increase as impedance increases.

Thus, in one example, the logic may determine the current level of battery degradation and/or current amount of swelling by identifying a current impedance of the battery as measured by the impedance sensor. The logic may then access a data table correlating impedance at various temperatures in a first column to corresponding levels of battery degradation and/or amounts of swelling respectively in second and/or third columns. The logic may then parse entries in the first column of impedances at various temperatures (and/or impedance ranges at various temperatures) until the logic identifies an entry in the first column for an impedance (and/or an impedance range) that matches the measured impedance at the measured temperature (or within which the measured impedance falls, if entries in the first column are for impedance ranges). The logic may then identity and/or estimate a current degradation and/or swelling by moving horizontally over from the matched entry in the first column to the second and/or third columns to identity data therein, e.g.. indicating a level of degradation and/or amount of swelling correlatable to the measured impedance at the measured temperature.

Still in reference to FIG. 3, from block 304 the logic next proceeds to block 306. At block 306 the logic may identify the current age of the battery and/or number of (e.g., post-manufacture and/or post-vending) charge cycles it has undergone. The logic may identify this data at block 306 by ascertaining the current time. date. etc. from an electronic clock and also accessing data (e.g., stored in the battery's battery management unit/system (BMU)) indicating age, dates, and/or other temporal information, as well data regarding the number of charge cycles the battery or batteries in the battery pack have undergone (where that historical data, e.g., may hive been incrementally stored by the BMU as additional charge cycles are undergone and data is generated based thereon).

From block 306 the logic moves to block 308, where the logic estimates and or determines a current expected impedance for the battery (e.g., at the current actual temperature of the battery), in contrast to the actual current impedance for the battery determined at block 304. The logic may estimate and/or determine current expected impedance, e.g., based on expected impedance being directly correctable to battery age and/or charge cycles undergone. Thus, for instance, impedance may be expected to increase as age and charge cycles undergone increase. The logic may estimate and/or determine the current expected impedance once historical data related to battery age and/or number of charge cycles undergone arc identified at block 306 by taking this data and comparing it against data in a data table respectively correlating battery age and/or charge cycles in respective columns with expected impedances (e.g., at various current temperatures) in another respective column until a match is identified in the data table to the current age and/or charge cycles undergone to then identify a current expected impedance in the expected impedance column, which may be done similarly to how the logic identified other data in a data table as described in reference to block 304 above, mutatis mutandis.

Furthermore, in some embodiments at block 308 and at least in part based on the age of the battery and/or number of charge cycles identified at block 306, the logic may also estimate and/or determine an expected current level of battery degradation and/or an expected current amount of battery swelling, e.g., based on expected degradation/swelling being directly correctable to battery age and/or charge cycles undergone. Thus, for instance, degradation/swelling may be expected to increase as age and charge cycles increase. The logic may estimate and/or determine the expected current swelling/degradation once expected impedance is identified. The expected impedance may be compared against data in a data table respectively correlating expected impedance, age, and/or charge cycles in respective columns with expected swellings degradation in other respective columns until a match is identified in the data table for expected impedance to then identify expected swelling/degradation, which may be done similarly to how the logic identified other data in the other data tables described above, mutatis mutandis.

With respect to at least some of the data in the data tablet(s) that may be accessed at block 308 (such as data related to expected impedances at various battery temperatures as correlated to respective battery ages and/or charge cycles undergone, and/or such as data related to expected swelling-degradation as correlated to expected impedance, age, and/or charge cycles undergone), this data may be established based in least in part on battery qualification test data determined, identified, and/or generated at manufacture of the battery pack and/or before vending of the battery back to a customer. For instance, a manufacturer of the battery pack may put the battery pack through a series of tests at manufacture and before placing it in the marketplace, where the battery pack is tested under various operating conditions (e.g., temperatures) and/or by charging, discharging, and again charging the batteries within the battery pack and measuring changes in impedance, swelling, degradation, etc. to then estimate expected impedances, expected swelling, and/of expected degradation at other temperatures, ages, and/or charge cycles undergone based on trends identified from the testing. The manufacturer may then populate these estimates in a data table for later access by a processor undertaking the logic of FIG. 3 in accordance with present principles.

In any case, from block 308 the logic next moves to block 310. At block 310 the logic identifies at least one impedance threshold (and/or swelling or degradation threshold), where when above the threshold, current actual battery impedance (and/or swelling and/or degradation determined based on current actual battery impedance) may be indicative of undesirable swelling/degradation for which the battery should be shorted to ground, rendered permanently inoperable, etc., such as for safety reasons. The threshold data may be stored in storage accessible to the logic, such as storage in the battery pack's BMU. Furthermore, it is to be understood that the threshold may vary based on age, charge cycle amounts, and the battery's current temperature, so that the threshold increases as age, charge cycle amounts and the battery's current temperature respectively increase. Accordingly, in some embodiments a data table correlating age, charge amounts, and/or battery temperatures with various impedance thresholds that are to be used under those conditions may be accessed at a storage area for the logic to identity an appropriate impedance threshold to use under current conditions.

Note that as indicated on the face of FIG. 3, in some embodiments multiple impedance thresholds may be used. For instance, a first impedance threshold may be the expected impedance under those operating conditions and/or based on the battery's history (or may be an impedance just above the expected impedance), and/or may be the upper bound of an expected impedance range if ranges are used (or an impedance just above the expected impedance range). A second impedance threshold, one which if current actual impedance exceeds this threshold the battery may be shorted to ground, may vary in the respect that it may be established as an amount a particular percentage (e.g., such as five percent) in excess of the first threshold and/or expected impedance amount, whatever the first threshold and/or expected impedance amount are determined to be in accordance with present principles. So. for example, the second impedance threshold may be identified as the amount of the first impedance threshold plus five percent of the amount of the first impedance threshold.

In any case, after identifying an applicable impedance threshold(s) based on current operating conditions and/or historical data, the logic moves from block 310 to decision diamond 312. At decision diamond 312, the logic determines, based on the input from the impedance sensor at block 302, whether the current actual impedance of the battery is above the first impedance threshold and/or the expected impedance.

If a negative determination is made at diamond 312, this causes the logic to move to block 314, at which the logic permits the battery to be subsequently charged a predetermined and or threshold number of times, and also at which charge cycles may be tracked and/or fogged such as using a cycle timer and/or cycle counter. However, note that in other embodiments at block 314, such as responsive to a negative determination at diamond 316 (which will be described shortly), the logic may instead permit the battery to discharge by a predetermined amount (e.g., voltage) and/or for a predetermined amount of time while preventing the battery from charging.

Then, responsive to the predetermined number of subsequent charges (e.g., 10 charges, 300 charges, etc.) being reached (and/or a total number of charges over the life of the battery or end-user use of the battery being reached), and/or based on the predetermined amount of discharge referenced in the paragraph above being reached or the predetermined amount of time referenced in the paragraph above expiring, the logic may return to decision diamond 312 and again make the determination described above. Before moving on, note that these charge cycles need not be, e.g., from at or near zero percent charge to at or near one hundred percent charge, but can be charge cycles such as discharging to sixty percent from approximately one hundred percent and then charging to ninety percent.

Regardless, once an affirmative determination is made at diamond 312, the logic may move from decision diamond 312 to decision diamond 316 if first and second thresholds are to be used, although it is to be understood mat in other example embodiments an affirmative determination at diamond 312 may cause the logic to proceed directly to block 318. which will be described shortly. However, first describing diamond 316. here the logic may determine, based on the input from the impedance sensor, whether the current actual impedance of the battery is above the second impedance threshold, and/or whether the current actual impedance of the battery is greater than the expected impedance by more than a predetermined threshold amount (e.g., by more than five percent of the expected impedance). A negative determination causes the logic to move lo block 314 and proceed therefrom as described above.

However, an affirmative determination at diamond 316 instead causes the logic to proceed to block 318. At block 318 the logic, responsive to the determination that the current actual impedance is above the second impedance threshold and/or the expected impedance by more than the predetermined threshold amount, shorts the battery to ground, initiates a (e.g., permanent) failure of the battery so that it can no longer be used by the device in which it is disposed, and/or renders the battery (e.g., permanently) inoperable (e.g., without replacing parts or a person physically altering the battery).

Notwithstanding, note that at block 318 the battery may not be shorted to ground immediately in some embodiments. For instance, the logic may initiate a “failure” of the battery in that the battery is permitted to discharge (while providing power to device so that the device may continue to function), but is not permitted to charge even if engaged with a charge source, until actual real time impedance is subsequently determined to be below the second threshold again (at which point the logic may return to a previous point and proceed therefrom, such as block 302 or diamond 312). If and when actual impedance is determined to again be below the second threshold, charging of the battery may thereafter be permitted and the battery may continue to be used to power the device. However, if actual impedance upon a subsequent (e.g., periodic) determinations) is still not determined to be below the second threshold, in this example battery discharge may be permitted until a low voltage threshold for the battery is reached, at which point the battery may be shorted to ground responsive to reaching the low voltage threshold and thus rendered inoperable.

However, in still other embodiments, at block 318 the battery may not be shorted to ground immediately and the periodic/actual impedance determinations referenced in the paragraph above need not be made. Thus, the logic may simply initiate a “failure” of the battery in that the battery is permitted to discharge but is not permitted to charge until a low voltage threshold for the battery is reached (regardless of if impedance begins to drop), at which point the battery may be shorted to ground responsive to reaching the low voltage threshold.

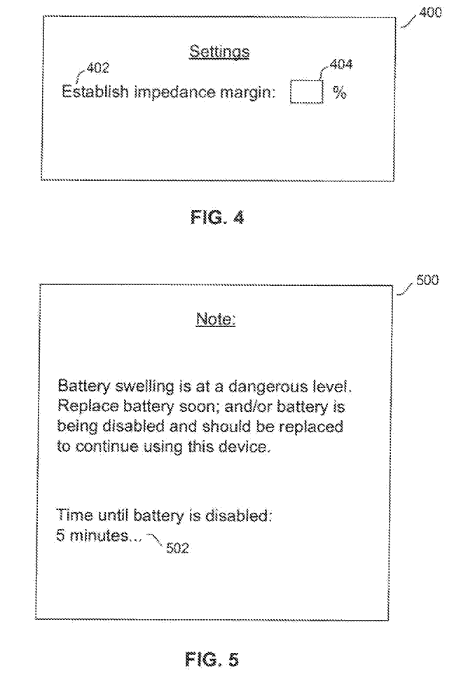

Reference is now made to FIG. 4. which shows an example user interface (UI) 400 presentable on a display of a device to configure one or more settings of a battery pack in accordance with present principles. Thus, the UI 400 may be presented on a manufacturer's display for programming a battery pack's BMU (or the device in which the battery pack is disposed) to undertake present principles. The UI 400 may also be presented on a display of a device associated with an administrator and/or user authorized to configure settings for a battery pack in accordance with present principles, even alter manufacture and sale of the battery pack and/or device in which it is disposed. In any case, example settings that may be included on the UI 400 may include respective settings to permit a person to establish the first and second thresholds described above (e.g., at various temperatures, ages, and/or charge cycles) using respective input boxes presented on the UI 400, and/or to establish an impedance margin as shown for setting 402 using input box 404. The impedance margin may be established as the amount between an expected impedance (e.g., at a particular battery temperature, age, and/or charge cycles undergone) and an impedance threshold at which the battery is to be shorted to ground.

Turning now to FIG. 5, it shows an example prompt 500 that may be presented on a display of a device in which a battery pack in accordance with present principles is disposed. The prompt 500 may be presented on a user's device when, e.g., impedance is determined to be higher than a threshold as disclosed herein. Thus, the prompt 500 may indicate, for example, that a battery in the device is swelling and is at a dangerous level. The prompt 500 may also indicate that the battery should be replaced soon, and/or that the device (and/or battery's BMU) is disabling the battery and that the battery should be replaced immediately. In some examples, if the battery is to not be disabled for, e.g., a threshold amount of time after current actual battery impedance is determined to be above the relevant threshold so that the user can be presented with the prompt 500 and take potential actions such as saving documents and transferring files before battery disablement, information on this lime may also be presented as part of the prompt 500. For example, an indication/counter 502 may be presented that indicates current time remaining prior to battery disablement and/or grounding.

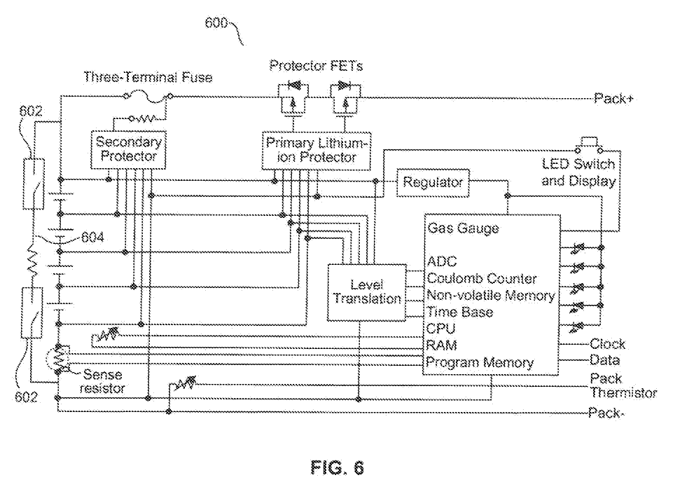

Continuing the detailed description in reference to FIGS. 6-9B, they show examples of how a battery may be shorted to ground, rendered permanently inoperable, and/or caused to permanently fail once an impedance threshold is reached as described herein.

Referring first to FIG. 6, it shows an example block diagram of battery pack circuitry 600 including hardware elements to short a battery to ground. Thus, in addition to other battery components such as protectors, a gas gauge, a regulator, and fuses, the circuitry 600 includes at least one, and optionally plural, switches 602 which may be, in some example embodiments, field effect transistors (FETs). The circuitry 600 may also include a resistor 604 which, when two switches 602 are used such as in the example embodiment shown, is between and connected to the two switches 602. Notwithstanding, whether one or plural switches are used, the switch(es) 602 and resistor 604 combination are understood to form a path from the battery cells to ground when the switch(es) 602 is actuated (e.g., by a processor and/or circuit responsive to an impedance threshold being reached as described herein and/or responsive to the low voltage threshold described above being reached) to permit current to flow to ground to discharge the battery, e.g., entirely or near entirely.

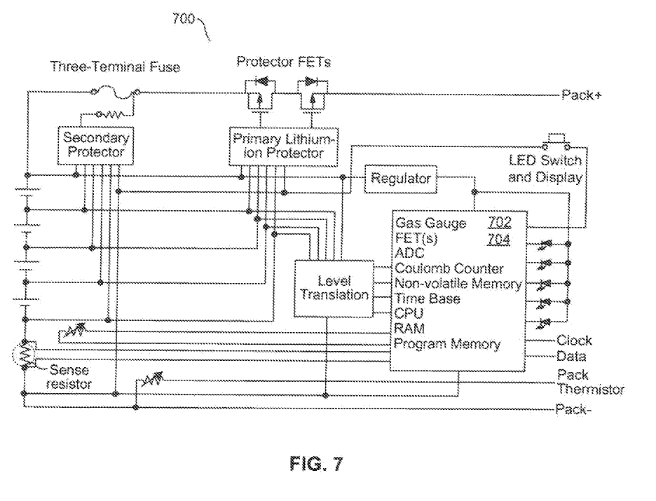

Continuing now in reference to FIG. 7, another example will be described of circuitry for shorting a battery to ground based on an impedance threshold being reached and/or based on a low voltage threshold being reached. FIG. 7 shows a block diagram of battery circuitry 700 including hardware elements that, based on software that is executed, are actuatable to short the battery shown to ground to discharge the battery.

The circuitry 700 comprises a battery gas gauge and/or BMU 702 in addition to other battery components such as protectors, a regulator, and fuses. As may be appreciated from FIG. 7, the gas gauge 702 may comprise an analog-to-digital converter (ADC), a coulomb counter, non-volatile memory, a time base, a processor, random access memory (RAM), and program memory.

The gas gauge 702 may also comprise at least one field effect transistor (FET) 404 (or another type of electrical switch), it being recognized that in some embodiments additional FETs in parallel may be included for bleeding current using respective resistors. In any case, the FET 704 is understood to be connected to a (e.g., balance and/or bleeding) resistor that may be external to the gas gauge 702 but within the circuitry 700, where this resistor is connected to ground or to a system component outside the battery.

The processor in the gas gauge 702 may thus execute instructions (e.g., software/firmware) stored in the gas gauge 702 to actuate the FET 704 to complete the path to ground or to the system component responsive to an impedance threshold being reached and/or a low voltage threshold being reached in accordance with present principles. In example embodiments, the processor may do so via the processor actuating the FET 704 to open and/or establish a path to the resistor described above (that may be external to the gas gauge 702 but within the circuitry 700), where this resistor is connected to ground, or to a system component, to thus discharge the battery and/or short it to ground. Even further, in some example embodiments, the processor may do so by actuating plural FETs in parallel in the gas gauge 702 to establish respective paths to respective resistors connected to ground or to a system component.

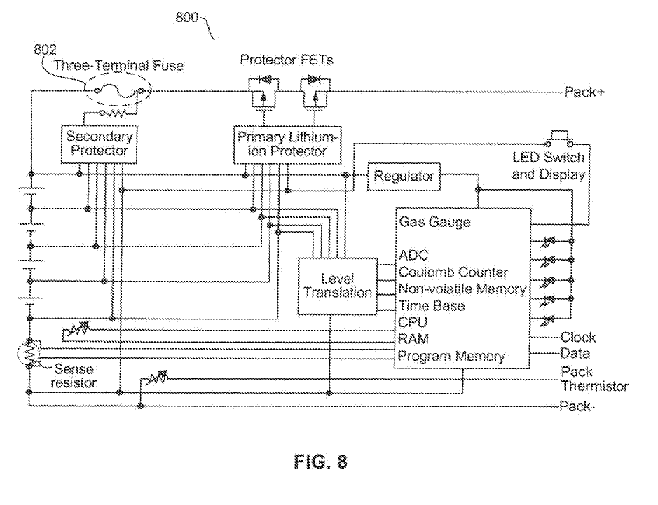

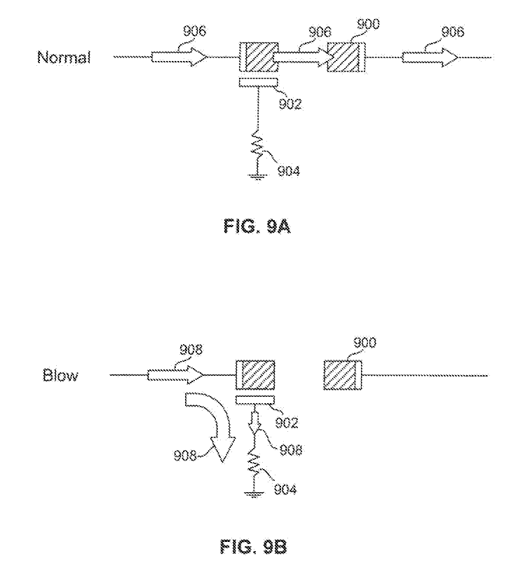

Continuing the detailed description with reference to FIG. 8, another example will be described of circuitry for shorting a battery to ground and/or discharging the battery. FIG. 8 shows a block diagram of battery circuitry 800 including battery components such as such as protectors, a regulator, and a gas gauge. Bubble 802 demonstrates a location within the circuitry 800 at which an example fuse in accordance with present principles may be disposed. This fuse is shown in more detail in FIGS. 9A and 9B.

Accordingly, reference is now made to FIGS. 9A and 9B, which are block diagrams of the operation of an example fuse 900 in accordance with present principles. FIGS. 9A and 9B also show that the fuse 900 may comprise a pad/terminal 902 electrically connected to a first resistor 904. where the first resistor 904 is connected to ground (or, in some embodiments, to a system component outside the battery). The resistor 904 may be part of the fuse 000 or external to it.

In example embodiments, the fuse 900 may comprise solder that connects two pads terminals of the ruse 900 while the ruse 900 is operating under normal conditions and/or is not shown, as represented by arrows 906 in FIG. 9A. However, note that the solder is not shown in FIGS. 9A and 9B for clarity. Also not shown for clarity in FIGS. 9A and 9B is an electrical component such as a second resistor that may be part of the fuse 900. The second resistor is under the solder, contacting the solder, and/or is proximate to the solder to thermally influence the solder. This second resistor is also connected to both the battery's cell stack and system load. Thus, to blow the fuse 900 to accelerate discharge to ground, an FET (which may be controlled by the battery's gas gauge, the battery's secondary protector integrated circuit, and/or a CPU of the device in which the battery is disposed) to ground may be opened, such as responsive to current actual impedance of the battery reaching a threshold at which the battery is to be shorted to ground in accordance with present principles and/or responsive to a low voltage threshold for the battery being reached at which the battery is to be shorted to ground in accordance with present principles. When the FET is opened, current is pulled through the second resistor lo heal the solder in the fuse 900.

As may be appreciated from FIG. 9B, when enough current is pulled through the second resistor, the second resistor heats the solder at least to the solder's melting point and, as the solder melts, it breaks the electrical connection of the two pads with which it was previously connected to thus blow the fuse 900. The melted solder's also contacts the pad 902 when blowing the fuse to establish an electrical connection between the pad 902 and the pad of the fuse 900 through which current enters the fuse 900 (one of the two pads not shown for clarity hut described above). In doing so, the melted solder establishes and or bridges a path for current to travel from the fuse 900 through resistor 904 and to ground (or to a system component) to accelerate discharge of the battery and or short the battery to ground. This path that is established is represented by arrows 908 as shown in FIG. 9B.

Regarding reference above to using a system component to accelerate discharge of the battery, this system component may be a component of the device in which the battery is disposed but not within the battery pack itself. For instance, a fan, an LED, or a resistor in a laptop computer may be turned on, remain on, and/or otherwise continue to drain current from the battery cells to accelerate discharge.

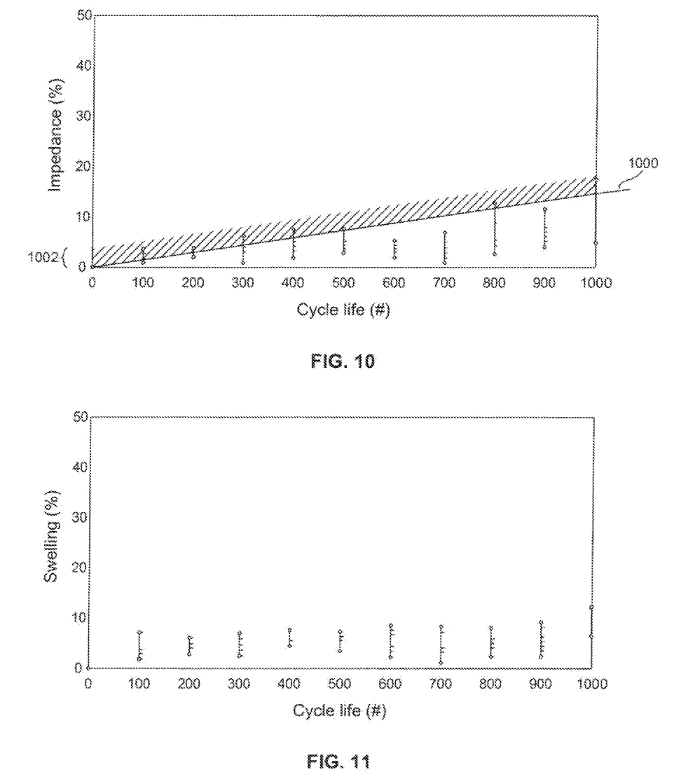

Moving on m the detailed description, reference is made to FIGS. 10 and 11. FIG. 10 shows that impedance 1000 of a battery may increase as the life of the battery and/or charge cycles undergone increase. Range 1002 is understood to represent a range above impedance 1000, where within the range 1002 the battery will not be triggered to fail even if current actual impedance is above impedance 1000 at that point in the battery's life. However, if current actual impedance is beyond the upper bound of the range 1002, the battery may be triggered to fail. As may be appreciated from FIG. 11, as impedance increases as shown in FIG. 10, swelling of the battery may also increase in some instances.

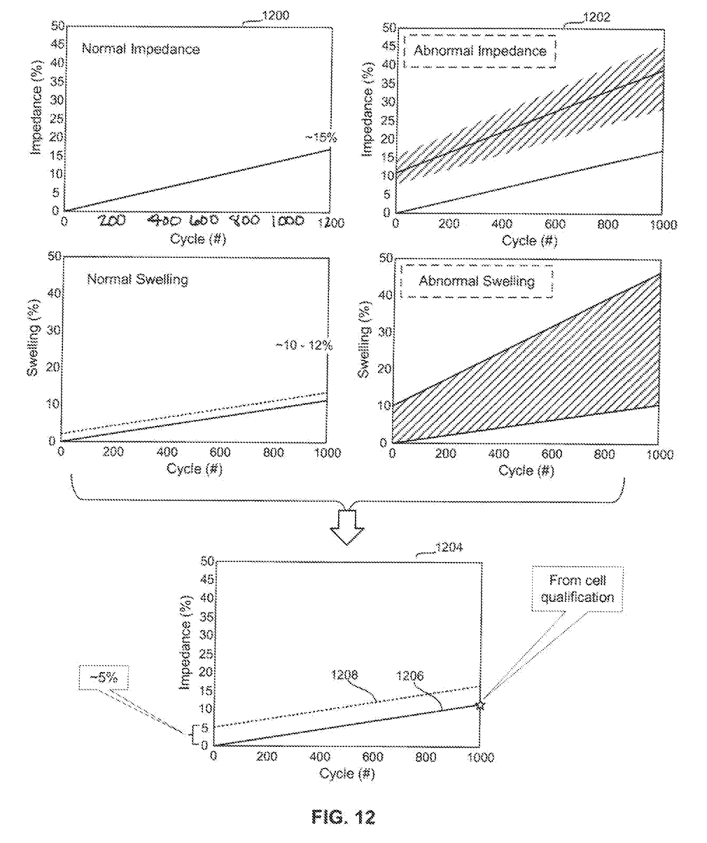

FIG. 12 also shows the relationship between swelling and impedance during cycling of a battery in accordance with present principles. The left column 1200 of graphs shows (at the top) expected impedance (labeled “normal impedance”) increasing by fifteen percent over the course of the life of the battery, and correspondingly shows (at the bottom) expected swelling (labeled “normal swelling”) increasing by ten to twelve percent as the battery's impedance increases over the course of the life of the battery. The column 1202 of graphs shows (at the top) unexpected and or abnormal impedance (labeled “abnormal impedance”) since it increases by more than expected, and correspondingly shows (at the bottom) unexpected and or abnormal swelling (labeled “abnormal swelling”) increasing by more than expected. Graph 1204 shows how an expected impedance 1206 (as determined based on cell qualification data) relative to an impedance threshold 1208 at which a battery may be rendered inoperable in accordance with present principles.

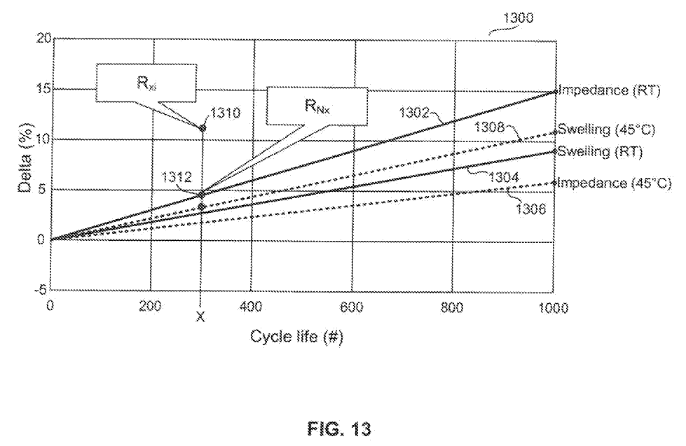

FIG. 13 shows another graph BOO illustrating present principles. Line 1302 shows impedance of a battery at room temperature may increase over the life of the battery and that swelling as show by line 1304 may thus also increase at room temperature over the life of the battery. Line 1306 shows impedance of the battery increasing at forty five degrees Celsius over the life of the battery and line 1308 correspondingly shows swelling increasing at forty five degrees Celsius over the life of the battery.

FIG. 13 also shows a point 1310 on the graph 1300 representing a current actual impedance of the battery al room temperature at a time in the battery's life cycle, while point 1312 represents an expected impedance al room temperature at that time. Accordingly, if current actual impedance at room temperature as measured in real time at that time in the battery's life cycle were at or below expected impedance at room temperature at that time, the battery pack may permit the battery to continue charging and discharging. If current actual impedance at room temperature at that time is above expected impedance at room temperature by more than a five percent difference between actual and expected impedance, the battery pack may trigger a failure of the battery. Thus, in the current example shown in FIG. 13, this is the ease since points 1310 and 1312 together show a difference of more than five percent, and hence the battery pack may trigger a permanent failure of the battery.

However, if current actual impedance at room temperature at that time is above expected impedance at room temperature but by less than the five percent difference between actual and expected impedance, the battery pack may continue permitting the battery to cycle through charges and then assess the gap between expected and actual impedance after a subsequent ten charge cycles, and/or the battery pack may permit the battery to discharge but not charge until actual impedance is at or below the expected impedance as periodically assessed by the battery pack (e.g., at a predetermined interval). In embodiments where charge cycling is permitted during this time as described in the sentence above, cycling may continue if impedance is reduced over time, but if actual impedance grows and eventually exceeds expected impedance by more than five percent at a later time, then the battery back may trigger a failure of the battery.

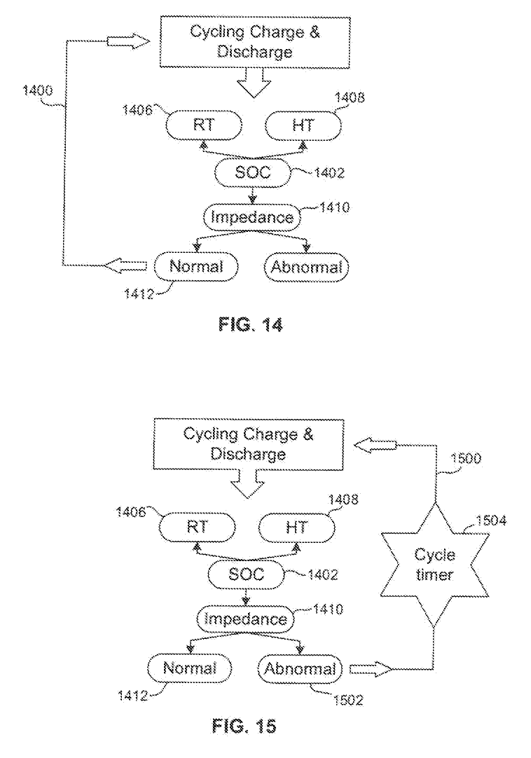

FIGS. 14 and 15 illustrate present principles as well. FIG. 14 shows path 1400 representing cycling charge and discharge of a battery in communication with a system on a chip (SOC) 1402 of a battery pack. The SOC 1402 receives input from a temperature sensor regarding whether a temperature of the battery is at, e.g., room temperature 1406 or high temperature 1408. The SOC 1402 also receives input from an impedance sensor regarding a measured current impedance 1410 of the battery. If the measured current impedance 1410 is less man or equal to an expected impedance at that point (represented by the “normal” bubble 1412) in the battery's life cycle, the battery may continue to cycle as represented by the path 1400.

However, as shown in FIG. 15, if the measured current impedance 1410 is above the expected impedance but by less than a threshold amount (e.g., five percent) at that point (represented by “abnormal” bubble 1502) in the battery's life cycle, the battery may set a cycle timer 1504 to count subsequent charge cycles and trigger (e.g., every ten charge cycles) the SOC 1402 to again assess how current actual impedance compares to expected impedance. Then, if current actual impedance exceeds expected impedance by more than the threshold amount as determined during one of these subsequent assessments, a permanent failure may be triggered.

It may now be appreciated in accordance with present principles that impedance may be measured in real time as a battery continues to operate, charge, discharge, and recharge, to determine whether current impedance is higher than a threshold at which a failure of the battery should be triggered by, e.g., permitting the battery to discharge but not recharge until current impedance falls below the threshold or reaches an expected level for that point in the battery's life. However, if current impedance is higher than normal but not above this threshold, the battery pack may continue monitoring impedance variation during subsequent cycling of the battery to determine if battery impedance exceeds the threshold at a later time. Furthermore, if the battery pack permits the battery to continue to discharge, but not charge, while impedance is still above the threshold to the point where a low voltage threshold for the battery is reached, the battery may be shorted to ground as disclosed herein.

It is to be understood in accordance with present principles that logic for undertaking present principles may be stored in storage and accessed by a processor for execution, but it may also or instead be implemented in an application specific integrated circuit (ASIC) and/or system on a chip (SOC).

Before concluding, it is to be understood that although a software application for undertaking present principles may be vended with a device such as the system 100, present principles apply in instances where such an application is downloaded from a server to a device over a network such as the Internet. Furthermore, present principles apply in instances where such an application is included on a computer readable storage medium that is being vended and or provided, where the computer readable storage medium is not a transitory signal and or a signal per se.

While the particular SHORTING BATTERY TO GROUND RESPONSIVE TO BATTERY IMPEDANCE REACHING THRESHOLD is herein shown and described in detail, it is to be understood that the subject matter which is encompassed by the present application is limited only by the claims.

What is claimed is:

1. A device, comprising:
a processor;
at least one system component accessible to the processor;
a battery which powers the processor and the at least one system component;
an impedance sensor that is accessible to the processor and that senses impedance of the battery; and
storage accessible to the processor and bearing instructions executable by the processor to:
receive input from the impedance sensor regarding an impedance of the battery; and
based at least in part on the input determine whether to perform at least one action to at least attempt to bring impedance of the battery below an impedance threshold

2. The device of claim 1, wherein the impedance threshold varies over time.

3. The device of claim 1, wherein the at least one action that is performed comprises permitting discharge of the battery but not charging of the battery.

4. The device of claim 1, wherein the al least one action that is performed comprises shorting the battery to ground.

5. The device of claim 1, wherein the instructions are executable by the processor to:
based at least in part on the input, estimate a level of degradation of the battery; and
based at least in part on the estimated level of degradation, determine whether to perform the at least one action to at least attempt to bring impedance of the battery below the impedance threshold.

6. The device of claim 1, wherein the instructions are executable by the processor to:
based at least in part on the input, estimate an amount of swelling of at least a portion of the battery; and
based at least in part on the estimated amount of swelling, determine whether to perform the at least one action to at least attempt to bring impedance of the battery below the impedance threshold.

7. The device of claim 6, wherein the amount of swelling is estimated based at least in part on data accessible to the processor.

8. The device of claim 1, comprising at least one battery temperature sensor, wherein the input is first input, and wherein the instructions are executable by the processor to:
receive second input from the at least one battery temperature sensor regarding a temperature of at least a portion of the battery; and
based at least in part on the first input and the second input, determine whether to perform the at least one action to at least attempt to bring impedance of the battery below the impedance threshold.

9. The device of claim 1, wherein the instructions arc executable by the processor to:
determine whether to perform the at least one action to at least attempt to bring impedance of the battery below the impedance threshold at least in part by determining, based at least in part on the input, whether the impedance of the battery is above the impedance threshold.

10. The device of claim 9, wherein the instructions are executable by the processor to:
in response to a determination that the impedance of the battery is below the impedance threshold but above an expected level of impedance permit the battery to be charged a predetermined number of charge cycles and responsive to the predetermined number of charge cycles being reached, again determine whether the impedance of the battery is above the impedance threshold.

11. The device of claim 9, wherein the instructions are executable by the processor to:
in response to a determination that the impedance of the battery is above the impedance threshold, permit the battery to discharge but not charge; and
responsive to a low voltage threshold for the battery being reached, short the battery to ground.

12. The device of claim 1, comprising a battery management unit (BMU), wherein the BMU comprises the processor.

13. The device of claim 1, wherein the processor is a central processing unit (CPU).

14. A method, comprising.
receiving input from a battery impedance sensor regarding an impedance of a battery; and
based at least in part on the input, determining whether the impedance of the battery is above an impedance threshold.

15. The method of claim 14, wherein the method comprises:
in response to determining that the impedance of the battery is above the impedance threshold, shorting the battery to ground.

16. The method of claim 14, wherein the method comprises:
in response to determining that the impedance of the battery is above the impedance threshold, permitting the battery to discharge but not charge.

17. The method of claim 14, wherein the method comprises:
in response to determining that the impedance of the battery is above the impedance threshold, rendering the battery inoperable.

18. The method of claim 14, wherein the impedance threshold is a first impedance threshold, and wherein the method comprises:
in response to determining that the impedance of the battery is above the first impedance threshold but below a second impedance threshold greater than the first impedance threshold, permitting continued operation of the battery at least until the battery is subsequently charged a predetermined number of times and then again determining whether the impedance of the battery is above the first impedance threshold.

19. The method of claim 14, wherein the input is first input, and wherein the method comprises:
receiving second input from a battery temperature sensor regarding a temperature of the battery; and
based at least in part on the first input and the second input, determining whether the impedance of the battery is above the impedance threshold.

20. A battery pack, comprising:
a battery;
an impedance sensor which senses an impedance of the battery; and
a processor powered by the battery and communicatively coupled to the impedance sensor, wherein the processor:
receives input from the impedance sensor; and
determines, based at least in part en the input, whether the impedance of the battery is above a threshold.

21. The battery pack of claim 20, wherein the processor one or more of:
shorts the battery to ground based on the impedance of the battery being above the threshold, permits the battery to discharge but not charge based on the impedance of the battery being above the threshold.
